(19) United States
(12) Patent Application Publication
(10) Pub. No.: US 2016/0322531 A1
(43) Pub. Date: Nov. 3, 2016

(54) SEMICONDUCTOR DEVICE AND OPTICAL COUPLING DEVICE

(71) Applicant: KABUSHIKI KAISHA TOSHIBA, Tokyo (JP)

(72) Inventor: Masaru KOSEKI, Kitakyushu Fukuoka (JP)

(21) Appl. No.: 15/060,519

(22) Filed: Mar. 3, 2016

(30) Foreign Application Priority Data
May 1, 2015 (JP) 2015-094267

(51) Int. Cl. H01L 31/16; H01L 23/00; H01L 23/495; H01L 23/498

(52) U.S. Cl. CPC H01L 31/16; H01L 23/49805; H01L 24/49; H01L 23/49575; H01L 2224/48101; H01L 2224/48105

(57) ABSTRACT

A semiconductor device in an embodiment comprises a first chip in a first resin and a second resin covering the first resin. A first lead frame is in the first resin and has a first end portion extending through the second resin. A second end portion of the first lead frame terminates in the second resin. A second lead frame is spaced from the first lead frame in the first resin. The second lead frame has a first end portion in the first resin and a second end portion that terminates in the second resin. The first chip is disposed on the first end portion of the second lead frame, and a first bonding wire electrically connects the first chip to the first lead frame.

### CROSS-REFERENCE TO RELATED APPLICATION

This application is based upon and claims the benefit of priority from Japanese Patent Application No. 2015-094267, filed May 1, 2015, the entire contents of which are incorporated herein by reference.

### FIELD

Embodiments of the present invention relate to a semiconductor device and an optical coupling device.

### BACKGROUND

An optical coupling device, which is also called a photo-coupler, includes a light emitting chip, a light receiving chip, a lead frame on which each of these chips is mounted, and a resin for covering them.

A portion of the lead frame protrudes outside the resin. Therefore, when adhesion between the resin and the lead frame is not high, moisture contacting the lead frame portion protruding from the resin may infiltrate into the resin due to a capillary phenomenon or the like, which may ultimately cause problems such as separation of the light emitting chip from the resin and failure of the device.

### DESCRIPTION OF THE DRAWINGS

FIG. 1 is a cross section diagram of a packaged optical coupling device.

FIG. 2A is a layout diagram of lead frames for a light emitting chip.

FIG. 2B is a layout diagram of lead frames for a light receiving chip.

FIG. 3A is a layout diagram of lead frames for a light emitting chip according to a comparative example.

FIG. 3B is a layout diagram of lead frames for a light receiving chip according to a comparative example.

FIG. 4 illustrates a manufacturing process of an optical coupling device according to an embodiment.

FIG. 5A is a layout diagram of lead frames before cutting.

FIG. 5B is a layout diagram of lead frames before cutting.

FIG.6 is a diagram showing an example in which end portions of the lead frames are provided on the same side.

### DETAILED DESCRIPTION

In general, according to one embodiment, a semiconductor device includes a first chip (e.g., a light-emitting diode chip) in a first resin. A second resin covers the first resin. A first lead frame is in the first resin and has a first end portion extending through the second resin to the outside. A second end portion of the first lead frame terminates in the second resin—that is, the end is within the second resin and does not penetrate completely through the full thickness of the second resin. A second lead frame is also in the first resin, but spaced from the first lead frame. The second lead frame has a first end portion disposed in the first resin and a second end portion terminating in the second resin. The first chip is disposed on the first end portion of the second lead frame. A first bonding wire electrically connects the first chip to the first lead frame either directly or via the second lead frame.

Embodiments of the present invention will be described below with reference to the accompanying drawings. In the following embodiments, the characteristic configuration and operation of a semiconductor device and an optical coupling device will be mainly described, and there are configurations and operations not explicitly described but that are readily apparent in view of the present disclosure or otherwise known to those of ordinary skill which are also included in the scope of the present disclosure.

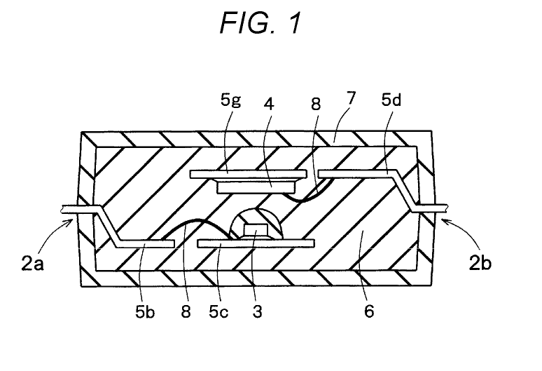

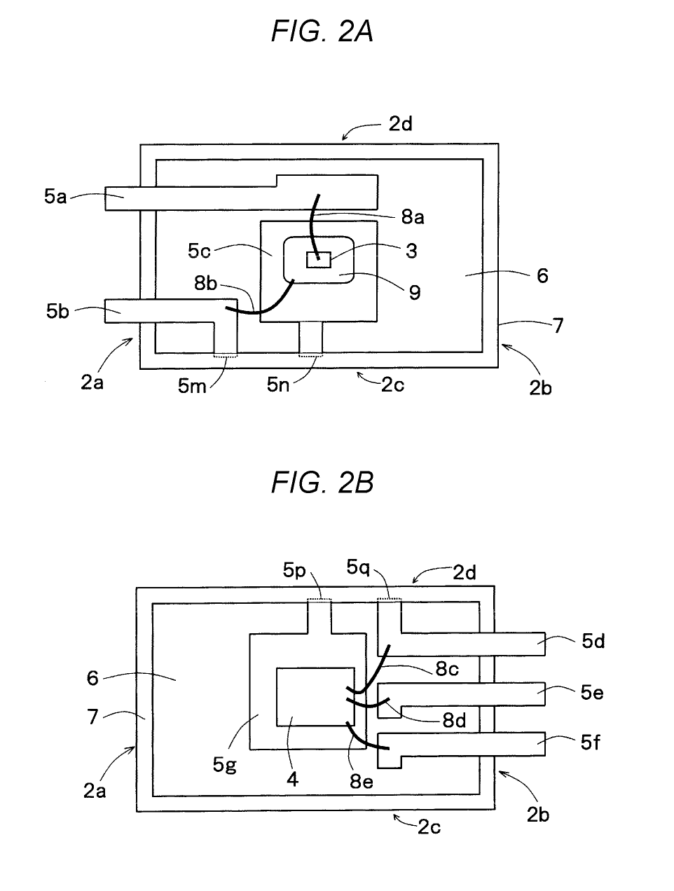

FIG. 1 is a cross section diagram of an optical coupling device 1. The optical coupling device 1 includes a light emitting chip (first chip) 3, a light receiving chip (second chip) 4, a plurality of lead frame elements 5a-5g (see FIGS. 1, 2A, and 2B), a first resin portion 6 and a second resin portion 7.

The light emitting chip 3 may be a chip only including a light emitting element, or may include a packaged substrate on which a light emitting element is mounted with various circuit elements associated with operation and/or control of the light emitting element. The light receiving chip 4 is a semiconductor device including a light receiving element therein.

The light emitting chip 3 and the light receiving chip 4 are disposed such that they face each other in a vertical direction (e.g., up-down page direction in FIG. 1), and the chips 3 and 4 are covered with the first resin portion 6, which is an inner resin portion. Light emitted from the light emitting chip 3 is transmitted through the first resin portion and is received by the light receiving chip 4. The first resin portion 6 covers both the light emitting chip 3 and the light receiving chip 4, and also covers at least a portion of the lead frames 5a-5g. The second resin portion 7, which is an outer resin portion, covers the entire first resin portion 6. Thus, the optical coupling device 1 has a double mold structure including the first resin portion 6 and the second resin portion 7.

Since the first resin portion 6 is transparent, even when the first resin portion 6 is present between the light emitting chip 3 and the light receiving chip 4, light from the light emitting chip 3 may be received by the light receiving chip 4 without significant loss. In this case, transparent means that there is a significant degree of transparency to an emission wavelength of the light emitting chip 3, but it is not required for the first resin portion 6 be entirely non-absorbing at the emission wavelength.

The second resin portion 7 is a substantially non-transparent material (for example, black (absorbing) resin or white (reflecting) resin), which shields light coming from outside of the optical coupling device 1 so as to prevent the light receiving chip 4 from receiving light from the outside. In this case, non-transparent means that there is no significant transmission of light at the emission wavelength of the light emitting chip 3.

Among the plurality of lead frames 5a-5g, the lead frames 5a-5c are provided to achieve conduction to the light emitting chip 3, and the lead frames 5d-5g are provided to achieve electrical connections to the light receiving chip 4. The lead frames 5a-5g are arranged apart from one another.

FIG. 2A is a layout diagram of the lead frames 5a-5c for the light emitting chip 3. FIG. 2B is a layout diagram of the lead frames 5d-5g for the light receiving chip 4.

As shown in FIG. 2A, among the lead frames 5a-5c for the light emitting chip 3, the lead frame 5a extends from the inside of the first resin portion 6 to the outside of the second resin portion 7.

A portion of the lead frame (first lead frame) 5b is arranged in the first resin portion 6. One end portion of lead frame 5b is arranged outside the second resin portion 7. Another end portion 5m of lead frame 5b is disposed in the second resin portion 7. More specifically, the lead frame 5b is in an L-shape, as depicted in FIG. 2A. The one end portion of the lead frame 5b and one end portion of the lead frame 5a protrude outward from the second resin portion 7 on the end surface 2a side of the optical coupling device 1. The other end portion 5m of the lead frame 5b protrudes outward from the first resin portion 6 on the end surface 2c side of the optical coupling device 1, but does not extend through the second resin portion 7 to the outside of the optical coupling device 1. Thus, the end portion 5m of lead frame 5b terminates inside the second resin portion 7.

A portion of the lead frame (second lead frame) 5c is in the first resin portion 6, and one end portion 5n of lead frame 5c is disposed in the second resin portion 7. More specifically, the end portion 5n of the lead frame 5c protrudes outward from the first resin portion 6 on the end surface 2c side of the optical coupling device 1, and but terminates inside the second resin portion 7.

Thus, both of the end portion 5m of the lead frame 5b and the end portion 5n of the lead frame 5c are arranged on the end surface 2c side of the optical coupling device 1. The lead frame 5b and the lead frame 5c protrude from the first resin portion 6, and the protruding portions (5m and 5n) are covered with the second resin portion 7, thereby improving the adhesion between the first resin section 6 and the second resin portion 7.

The light emitting chip 3 is mounted on the lead frame 5c. The lead frame 5a is connected to an anode of the light emitting chip 3 by a bonding wire 8a. The lead frame 5b is connected to a cathode of the light emitting chip 3 by another bonding wire 8b. Although the lead frame 5b and the lead frame 5c are depicted as connected by the bonding wire 8b in FIG. 2A, the lead frame 5b and may instead be directly connected to a cathode terminal on the light emitting chip 3 by the bonding wire 8b.

The light emitting chip 3 and a portion of the bonding wires 8a and 8b are covered with a third resin portion 9 comprising a transparent silicone material. Transparent in this case also means that there is transparency to the emission wavelength of the light emitting chip 3.

The reason that the light emitting chip 3 is covered with the third resin portion 9 is as follows. An LED that includes the light emitting chip 3 is often made of a compound semiconductor (e.g., GaN), and the compound semiconductor is typically more brittle than silicon and generally has more inherent crystal defects therein. For this reason, the light emitting chip 3 is more easily affected by environmental temperature and stress, and therefore, is more easily deteriorated when formed of compound semiconductor. Therefore, the light emitting chip 3 is covered with the third resin portion 9, so as to be less affected by temperature changes and stress variations. When the light emitting chip 3 is made of silicon material, inclusion of the third resin portion 9 may be unnecessary.

As shown in FIG. 2B, among the lead frames 5d-5g for the light receiving chip 4, a portion of the lead frame (third lead frame) 5d is arranged in the first resin portion 6, one end portion of lead frame 5d is outside the second resin portion 7, and the other end portion 5q of lead frame 5d is in the second resin portion 7. More specifically, the lead frame 5d is in an L-shape, with one end portion of the lead frame 5d protruding outward from the second resin portion 7 on the end surface 2b side of the optical coupling device 1 and the end portion 5q of the lead frame 5d protruding outward from the first resin portion 6 on the end surface 2d side of the optical coupling device 1 but terminating inside the second resin portion 7.

The lead frames 5e and 5f extend from inside of the first resin portion 6 to the outside of the second resin portion 7. More specifically, end portions of the lead frames 5d, 5e and 5f protrude outward from the second resin portion 7 on the end surface 2b side of the optical coupling device 1.

For the lead frame (fourth lead frame) 5g a portion on which the light receiving chip for is disposed is inside the first resin portion 6 and one end portion 5p of the lead frame 5g protrudes outward from the first resin portion 6 on the end surface 2d side of the optical coupling device 1 and terminates inside the second resin portion 7.

Thus, both of the end portion 5q of the lead frame 5d and the end portion 5p of the lead frame 5g are arranged on the end surface 2d side of the optical coupling device 1. These end portions (5q and 5p) of lead frame 5d and the lead frame 5g protrude from the first resin portion 6 and are covered with the second resin portion 7, thereby improving the adhesion between the first resin section 6 and the second resin portion 7.

The light receiving chip 4 is mounted on the lead frame 5g. The lead frames 5d, 5e and 5f are connected to the light receiving chip 4 by different bonding wires 8c, 8d and 8e, respectively. The lead frames 5d and 5f are connected to, for example, a grounding terminal of the light receiving chip 4, and the lead frame 5e is connected to, for example, a power supply terminal of the light receiving chip 4.

Note that the number and arrangement of the lead frames provided in the optical coupling device 1 are not limited to those specifically depicted in the figures. In some embodiments, the optical coupling device 1 may be a surface mounted type, such as an SOP (Small Outline Package), or may be an insert-mounted type, such as a DIP (Dual Inline Package). A multi-channel configuration in which a plurality of light emitting chips 3 and the light receiving chips 4 are incorporated into one optical coupling device 1 may also be adopted.

As described above, a first feature of the present embodiment is that the lead frame 5b (connected to the cathode of the light emitting chip 3) and the lead frame 5c (on which the light emitting chip 3 is mounted) are arranged apart from each other, and the lead frame 5d (connected to the grounding terminal of the light receiving chip 4) and the lead frame 5e (on which the light receiving chip 4 is mounted) are arranged apart from each other. Further, a second feature of the present embodiment is that respective end portions 5m and 5n of the lead frames 5b and 5c for the light emitting chip 3, and the respective end portions 5q and 5p of the lead frames 5d and 5g for the light receiving chip 4 terminate in the second resin portion 7.

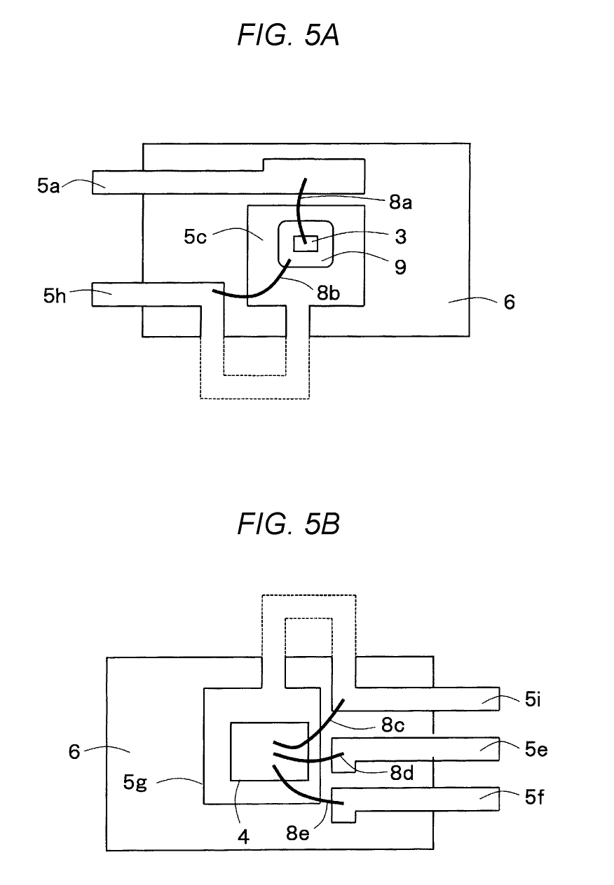

The lead frame 5b and the lead frame 5c may be formed by cutting of a single lead frame 5h, for example (see FIG. 5A). Similarly, the lead frame 5d and the lead frame 5g may be formed by cutting of a single lead frame 5i (see FIG. 5B), for example. Thus, the cut surfaces forming the respective end portions 5m and 5n of the lead frames 5b and 5c maybe aligned with the end surface 2c side of the optical coupling device 1, and similarly, the cut surfaces forming the respective end portions 5q and 5p of the lead frames 5d and 5g may be aligned with the end surface 2d side of the optical coupling device 1. Therefore, these cut surfaces forming the end portions 5m, 5n, 5p and 5q may be disposed outside the first resin portion 6 and inside the second resin portion 7.

As described above, the lead frame 5b and the lead frame 5c are arranged apart from each other, thus, moisture condensing on or otherwise contacting the lead frame 5b which protrudes outward from the outer surface of the optical coupling device 1 is unable to easily reach the light emitting chip 3 via a pathway created or provided by the lead frame 5b because the lead frame 5b is not directly connected to the light emitting chip 3. Similarly, the lead frame 5d and the lead frame 5g are arranged apart from each other, thus, moisture condensing on or otherwise contacting the lead frame 5d connected to the grounding terminal which protrudes outward from the outer surface of the optical coupling device 1 is unable to easily reach the light receiving chip 4 via a pathway created or provided by the lead frame 5d.

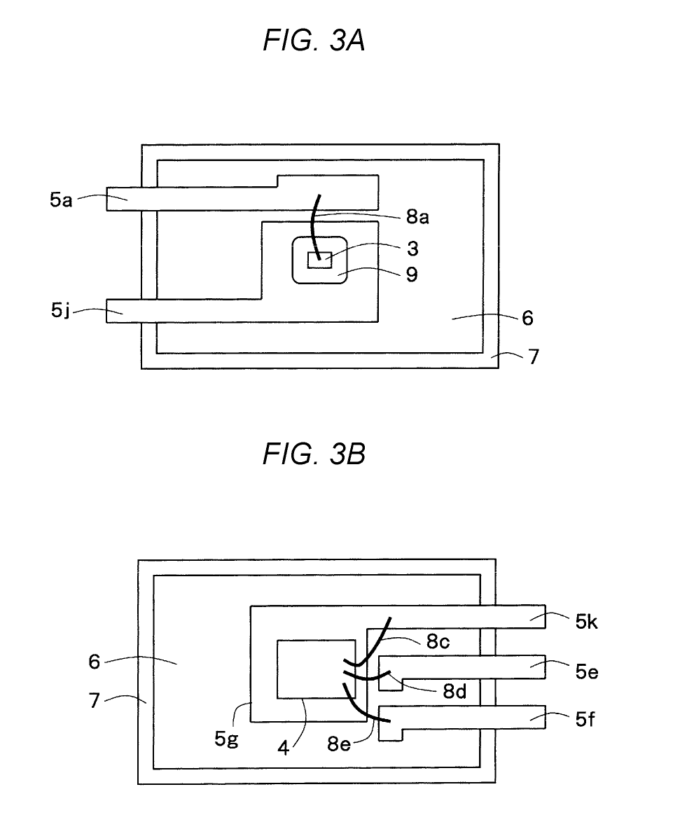

FIG. 3A is a layout diagram around lead frames 5a and 5j for the light emitting chip 3 according to a comparative example, and FIG. 3B is a layout diagram around lead frames 5k, 5e and 5f for the light receiving chip 4 according to a comparative example.

As shown in FIG. 3A, according to the comparative example, the lead frame 5j for the cathode extends between the inside of the first resin portion 6 and the outside of the second resin portion 7, and one end thereof is wider than the other end (the protruding end) so that the light emitting chip 3 can be mounted thereon. The shape of the lead frame 5a for the anode is similar to that depicted in FIG. 2A.

Further, as shown in FIG. 3B, according to the comparative example, the lead frame 5k for the grounding terminal extends between the inside of the first resin portion 6 and the outside of the second resin portion 7, and one end is wider than the other end (protruding end) so that the light receiving chip 4 can be mounted thereon. The shape of the two remaining lead frames 5e and 5f are similar to those depicted in FIG. 2B.

As depicted in FIG. 3A, since the light emitting chip 3 is mounted on one end of the lead frame 5j, there is a risk that moisture condensing or otherwise contacting the lead frame 5j which protrudes outward from the second resin portion 7 may reach and penetrate the third resin portion 9 through a pathway created or provided by the lead frame 5j. If moisture intrudes into the optical coupling device 1, separation between the lead frame 5j and a third resin portion 9 or the first resin portion 6, between the light emitting chip 3 and the third resin portion 9, and between the third resin portion 9 and the first resin portion 6 occurs sequentially from a place having weaker adhesion, depending on the difference among linear expansion coefficients, and stress between respective members configuring the optical coupling device 1 is alleviated by cracking and/or separation. Typically, since the interface between the lead frame 5j and the third resin portion 9 or the first resin portion 6 has the fewest number of hydrogen bonds, separation is most likely to occur at these points. Moisture intruding into a gap generated by separation between the resin materials and the lead frame materials rapidly intrudes from the interface toward the inside thereof because of a capillary phenomenon. In other words, moisture is unevenly and locally distributed in the optical coupling device 1, and further diffuses to a place where there is little moisture from the position where moisture intrudes. Thus, the separation of the light emitting chip 3 continues after the initial moisture intrusion. When moisture intrudes into the third resin portion 9 and the first resin portion 6, volume of these resin portions may change, and the linear thermal expansion coefficient of these materials may also change. By the change of the linear thermal expansion coefficient, separation may also be likely to occur and the adhesion between resin materials and lead frames may be lowered.

Furthermore, as depicted in FIG. 3B, the light receiving chip 4 is not covered with the third resin portion 9, but in a similar manner to the light emitting chip 3 side of the device, moisture intrudes into the optical coupling device 1 through a pathway created or provided by the lead frame 5k. The light receiving chip 4 is typically bonded to an end portion of the lead frame 5k with an adhesive agent, but when moisture reaches the light receiving chip 4 via the pathway provided or created by the lead frame 5k, the adhesion at the interface between the first resin portion 6 and the light receiving chip 4, and the interface between the adhesive agent and the light receiving chip 4 weakens and separation may occur at these interfaces. When separation occurs, moisture may further intrude into the gap generated by the separation due to a capillary phenomenon, and as even more moisture intrudes into device at these interfaces, and the separation of the various components may increase.

In contrast, in the present embodiment, as depicted in FIG. 2A, the lead frame 5b for the cathode and the lead frame 5c on which the light emitting chip 3 is mounted are arranged apart from each other. Therefore, even when moisture intrudes into the optical coupling device 1 through the pathway of the lead frame 5b, the moisture does not necessarily reach the lead frame 5c due the separation of these elements by at least the first resin portion 6. Similarly, a gap is also present between the lead frame 5a and the lead frame 5c, thus moisture entering the optical coupling device 1 through the pathway of the lead frame 5a also does not necessarily reach the lead frame 5c due to separation of these elements by at least the first resin portion 6. Therefore, a risk that moisture intrudes into the third resin portion 9 covering the periphery of the light emitting chip 3 is significantly reduced, thus, it is possible to prevent separation between respective members due to moisture intrusion from adversely affecting device operation.

Since the lead frames 5c and 5g on which the light emitting chip 3 and the light receiving chip 4 are mounted, respectively, are contained in the first resin portion 6 and the second resin portion 7, when deformation is generated by the linear thermal expansion coefficient difference between the lead frames 5c and 5g and the first and second resin portions 6 and 7, due, for example, to a temperature difference between the temperature at the time of molding and room temperature, and the temperature and humidity difference in an environment that the product operates in after shipment, the deformation in the longitudinal direction will be larger than that in the shorter direction according to the outer shape of the first and second resin portions 6 and 7 themselves because interfaces between the first and second resin portions 6 and 7 and the lead frames 5c and 5g are continuous. Since the interfaces between the first and second resin portions 6 and 7 and the lead frames 5c and 5g are fixed, the light emitting chip 3 and the light receiving chip 4 are deformed in such that the chips are pressed against the lead frames 5c and 5g. Consequently, separation of both of chips 3 and 4 from the lead frames 5c and 5g is suppressed, thus, the reliability is improved. On the other hand, in the comparative example in FIG. 3, since the lead frames 5j and 5k on which the light emitting chip 3 and the light receiving chip 4 are mounted, respectively, are not contained within the first resin portion 6 and the second resin portion 7, the portion where the interfaces between the resins 6 and 7 and the lead frames 5j and 5k are not continuous, that is to say, the portion where the lead frames 5j and 5k protrude from the second resin portion 7, is not fixed, and, from the boundary, a gap where separation between the second resin portion 7 and the lead frames 5j and 5k is started is generated, thus, reliability is reduced.

Similarly, in the present embodiment, as shown in FIG. 2B, the lead frame 5d for the grounding terminal and the lead frame 5g on which the light receiving chip 4 is mounted are arranged apart from each other. Therefore, even when moisture intrudes into the optical coupling device 1 through the lead frame 5d for the grounding terminal, the moisture does not reach the lead frame 5g on which the light receiving chip 4 is mounted. Similarly, a gap is also present between the lead frames 5e and 5f and the lead frame 5g. Therefore, it is possible to prevent separation between respective members due to moisture intrusion.

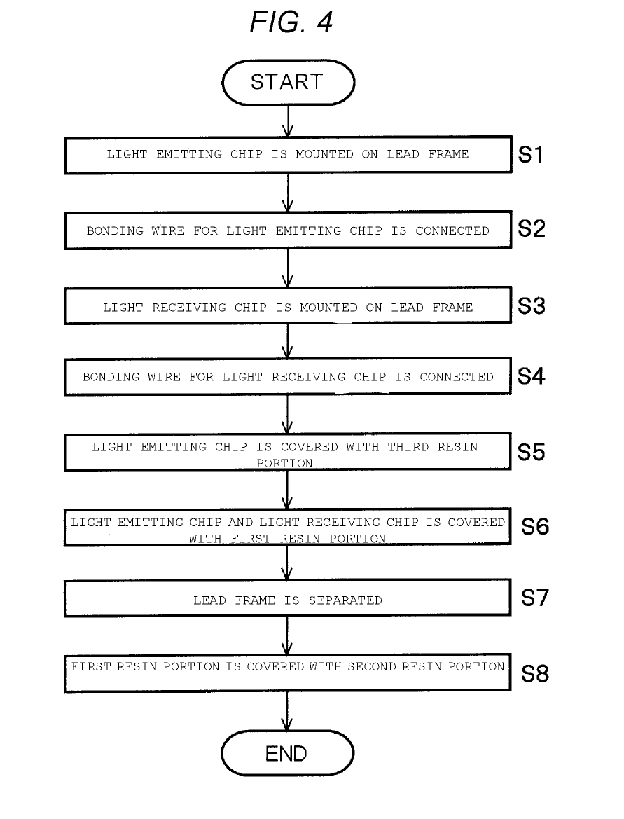

FIG. 4 is a flow chart illustrating a manufacturing process of the optical coupling device 1 according to the present disclosure. First, as shown in FIG. 5A, the light emitting chip 3 is mounted on the wide portion of the lead frame 5h, which is in a U-shape (step S1). Next, the light emitting chip 3 and the lead frame 5a for the anode are connected by the bonding wire 8a, and the wide portion of the lead frame 5h and the other end of the lead frame 5h are connected by the bonding wire 8b (step S2). The reason that the wide portion of the lead frame 5h and the other end of the lead frame 5h are connected by the bonding wire 8b is to achieve the electrical connection of the two lead frames 5b and 5c which will be formed by cutting the lead frame 5h.

Before or after the steps S1 and S2 described above, light receiving chip 4 is mounted on the wide portion of the lead frame 5i, one end of which is in a U-shape (step S3). Next, the light receiving chip 4 and the two lead frames 5e and 5f are connected by the bonding wires 8d and 8e, respectively, and the wide portion of the lead frame 5i and the other end of the lead frame 5i are connected by the bonding wire 8c (step S4). The reason that the wide portion of the lead frame 5i and the other end of the lead frame 5i are connected by the bonding wire 8c is to achieve the electrical connection of the two lead frames 5 which will be formed by cutting the lead frame 5i.

Next, the light emitting chip 3 and the bonding wires 8a and 8b are covered with the third resin portion 9 (step S5). By covering with the third resin portion 9, the light emitting chip 3 will be less affected by temperature changes and stress variations, and the separation of the bonding wires 8a and 8b may also be prevented.

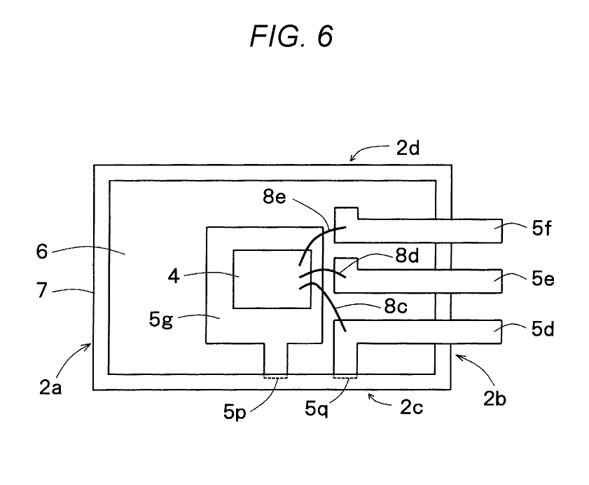

Next, the light emitting chip 3 and the light receiving chip 4 are vertically placed such that the chips face each other, and the chips are encased in (covered with) the first resin portion 6 (step S6). At this time, as shown in FIGS. 5A and 5B, the U-shaped portions of the lead frames 5h and 5i protrude outward from the outer surface of the first resin portion 6. As used herein, “U-shaped portion” includes any lead frame portion which reverses direction upon itself by approximately 180 degrees. The “U-shaped” portions of lead frames 5h and 5i as depicted in FIGS. 5A and 5B include two 90 degree bends or elbows; however, this is just an example and the “U-shaped” portion might be a smoothly curving portion including the equivalent of half circle. Also, in general, the “U-shaped portion” may take any arbitrary path from one end to the other end so long as the end result otherwise corresponds in general to the depictions of examples in FIG. 1, FIG. 2A, FIG. 2B, or FIG. 6.

Next, the portions (shown by broken lines in FIGS. 5A and 5B) of the lead frames 5h and 5i protruding outward from the outer surface of the first resin portion 6 are cut (step S7). Thus, the cut lead frame 5h forms the two lead frames 5b and 5c, and the cut lead frame 5i forms the two lead frames 5d and 5g. At this time, the certain end portions of the lead frames 5b, 5c, 5d and 5g slightly protrude outward from the outer surface of the first resin portion 6 as shown by the broken lines in FIGS. 2A and 2B, specifically end portions 5m, 5n, 5p, and 5q protrude slightly from the first resin portion 6. Since each of the protruding end portions 5m, 5n, 5p and 5q represents a fractured and/or jagged end surface (due to the cutting process), as compared to a smooth or flat end surface which results from, for example, a stamping or etching process used to make lead frames, adhesion to the second resin portion 7 may be increased because of an anchoring effect. The fractured and/or jagged end surface of protruding end portions 5m, 5n, 5p, and 5q resulting from cutting of the U-shaped portions of the respective lead frame elements may be referred to as a “cut end” surface.

Note that since the lead frame 5b and the lead frame 5c which are arranged apart from each other are connected by the bonding wire 8b, and similarly, the lead frame 5d and the lead frame 5g which are arranged apart from each other are connected by the bonding wire 8c, conductivity between these elements need not be impaired.

Next, as shown in FIGS. 2A and 2B, the first resin portion 6 is encased in (covered with) the second resin portion 7 (step S8). In step S7, even when the respective one end portions 5m and 5n of the lead frame 5b and 5c, and the respective one end portions 5p and 5q of the lead frame 5d and 5g protrude from the end surface of the first resin portion 6, by further covering with the second resin portion 7, the lead frames 5b, 5c, 5d and 5g would be completely covered and sealed from the exterior environment by the second resin portion 7.

The lead frames 5b, 5c, 5d and 5g protruding from the first resin portion 6 are engaged with the second resin portion 7, rather than penetrating completely through the second resin portion 7, thus, adhesion between the first resin portion 6 and the second resin portion 7 is improved. In order to achieve good workability, the length of the protrusion into the second resin portion 7 is approximately between 50 μm and 150 μm; more specifically, the range from 50 μm to 100 μm is more desirable such that the thickness of the second resin portion 7 does not change significantly. The thickness of the second resin portion 7 is approximately between 0.150 μm and 300 μm, because such thickness provides the necessary light shielding property and resin cracking is significantly generated at end portions 5m, 5n, 5p, and 5q of the lead frames 5b, 5c, 5d and 5g. In practice, the thickness of the second resin portion 7 and the protrusion depth of the end portions 5m, 5n, 5p, and 5q can be set according to desired strength and reliability of the end-use device.

When the lead frames 5h and 5i are cut at the portions shown by broken lines to form the lead frames 5b and 5c and the lead frames 5d and 5g, heat generated in the light emitting chip 3 and the light receiving chip 4 is less likely to pass through the lead frames 5b and 5d to escape to the outside of the optical coupling device 1. Thus, it is desirable to otherwise promote the diffusion of heat from the interior of optical coupling device 1, such as by expanding the area of the lead frames 5b, 5c, 5d and 5g on which the light emitting chip 3 or the light receiving chip 4 is mounted.

Thus, in this present embodiment, since the lead frame 5b connected to the cathode of the light emitting chip 3, and the lead frame 5c on which the light emitting chip 3 is mounted are arranged apart from each other, and the lead frame 5d connected to the grounding terminal of the light receiving chip 4 and the lead frame 5g on which the light receiving chip 4 is mounted are arranged apart from each other, even when moisture adhering to the lead frames 5b and 5d at the outside of the second resin portion 7 intrudes into the first resin portion 6 through the lead frames 5b and 5d, it is possible to prevent the moisture from reaching the lead frames 5c and 5g on which the light emitting chip 3 and the light receiving chip 4 are mounted, respectively, and to prevent separation at the interface between the third resin portion 9 and the light emitting chip 3 (light receiving chip 4) due to the moisture from the outside.

In addition, the end portions of the lead frames 5c and 5g protruding from the first resin portion 6 are engaged with the second resin portion 7, thus, adhesion between the second resin portion 7 and the first resin portion 6 may be improved. That is, the end portions 5m, 5n, 5p and 5q of the protruding lead frames 5b, 5c, 5d and 5g are arranged between the first resin portion 6 and the second resin portion 7 on the two facing end surfaces 2c and 2d side of the optical coupling device 1, thus, the adhesion between the first resin portion 6 and the second resin portion 7 may be enhanced. In particular, when the end portions 5m and 5n are arranged on the two facing end surfaces 2c and 2d side of the optical coupling device 1, symmetry is increased, and the lead frames 5c and 5g on which the light emitting chip 3 and the light receiving chip 4 are mounted, respectively, may be placed substantially at the center of the optical coupling device 1, thus, the strength of the optical coupling device 1 is increased.

### Second Embodiment

Although, in the first embodiment described above, the example is described that the respective one end portions of the lead frames 5d and 5g are provided on the end surface 2d opposite to the end surface 2c of the first resin portion 6 on which the respective one end portions of the lead frames 5b and 5c are provided, the respective one end portions of the lead frames 5b, 5c, 5d and 5g may be provided on the same end surface 2c side of the first resin portion 6.

FIG. 6 is a diagram showing an example in which the respective one end portions of the lead frames 5b and 5c are provided on the same side as respective end portions of the lead frames 5d and 5g. As may be seen by comparing FIG. 6 and FIG. 2B, the orientations of the respective one end portions of the lead frames 5d and 5g are reversed. Note that, in the second embodiment, the arrangement of the lead frames 5a-5c on the light emitting chip 3 side is the same as that in FIG. 2A.

When arranged as shown in FIG. 6, the respective one end portions of the lead frames 5b, 5c, 5d and 5g are provided on the end surface 2c side of the first resin portion 6. When the broken line portions are cut from the lead frames 5h and 5i, the broken line portions vertically arranged may be collectively cut, thus, the manufacturability is improved.

Although, in the first and second embodiments described above, the example applied to the optical coupling device 1 is described, the embodiments of the present disclosure may be widely applied to various semiconductor devices in which moisture adhering to a lead frame protruding outside the resin portion may intrude into the resin portion. Therefore, the semiconductor device to which the present embodiment may be applied does not necessarily have the light emitting chip 3 and the light receiving chip 4. According to the present embodiment, two separated lead frames (5b, 5c), (5d, 5g) are electrically conducted by the bonding wires 8b and 8c, and thus, it is possible to prevent moisture adhering to the lead frames protruding outside the resin portion from intruding around the various chips in the resin portion.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first chip in a first resin;
a second resin covering the first resin;
a first lead frame in the first resin and having a first end portion extending through the second resin and a second end portion terminating in the second resin;
a second lead frame in the first resin and spaced from the first lead frame, the second lead frame having a first end portion disposed in the first resin and a second end portion terminating in the second resin, the first chip being disposed on the first end portion of the second lead frame; and
a first bonding wire electrically connecting the first chip to the first lead frame.

2. The semiconductor device according to claim 1, wherein the second end portion of the first lead frame and the second end portion of the second lead frame are on a same side of the second resin.

3. The semiconductor device according to claim 1, further comprising:
a third resin on the first end portion of the second lead frame and covering the first chip and a portion of the first bonding wire, the third resin being between the first resin and the first chip.

4. The semiconductor device according to claim 1, further comprising:
a third lead frame in the first resin and spaced from the first and second lead frames, the third lead frame having a first end portion of extending through the second resin and a second end portion terminating in the second resin;
a fourth lead frame in the first resin and spaced from the first, second, and third lead frames, the fourth lead frame having a first end portion disposed in the first resin and a second end portion terminating in the second resin;
a second chip in the first resin and disposed on the first end portion of the fourth lead frame; and
a second bonding wire electrically connecting second chip to the third lead frame.

5. The semiconductor device according to claim 4, wherein the second end portion of the third lead frame and the second end portion of the fourth lead frame are provided on a same side of the second resin.

6. The semiconductor device according to claim 5, wherein
the second end portion of the first lead frame and the second end portion of the second lead frame terminate in the second resin on a first side of the second resin; and
the second end portion of the third lead frame and the second end portion of the fourth lead frame terminate in the second resin on a second side of the second resin opposite the first side.

7. The semiconductor device according to claim 5, wherein the second end portion of the first lead frame, the second end portion of the second lead frame, the second end portion of the third lead frame, and the second end portion of the fourth lead frame terminate in the second resin on a same side of the second resin.

8. The semiconductor device according to claim 4, wherein
the first chip is a light emitting chip configured to emit light,
the second chip is a light receiving chip configured to receive light emitted by the first chip,
the first resin is transparent at a wavelength of light emitted by the first chip, and
the second resin is opaque to the wavelength of light emitted by the first chip.

9. An optical coupler, comprising:
a light emitting element disposed on a first part of a first lead frame and surrounded by a first resin that is transparent to light from the light emitting element, a second part of the first lead frame extending from the first part in the first resin and terminating in a second resin surrounding the first resin, the second resin opaque to light from the light emitting element;
a second lead frame electrically connected to the light emitting element through a first bonding wire, a third part of the second lead frame element extending from the first resin through the second resin to outside the second resin, a fourth part of the second lead frame extending from the third part in the first resin and terminating in the second resin;
a light receiving element disposed on a fifth part of a third lead frame and facing the light emitting element, the fifth part and the light receiving element surrounded by the first resin, a sixth part of the third lead frame extending from the fifth part and terminating in the second resin; and
a fourth lead frame electrically connected to the light receiving element through a second bonding wire, a seventh part of the fourth lead frame extending from the first resin through the second resin to outside the second resin, an eighth part of the fourth lead frame extending from the seventh part and terminating in the second resin.

10. The optical coupler according to claim 9, further comprising:
a third resin covering the light emitting element and a portion of the first bonding wire, the third resin being between the light emitting element and the first resin.

11. The optical coupler according to claim 9, wherein the second part, the fourth part, the sixth part, and the eighth part terminate on a same side of the second resin.

12. The optical coupler according to claim 9, wherein the second part and the fourth part terminate on a first side of the second resin, and the sixth part and the eighth part terminate on a second side of the second resin opposite the first side.

13. The optical coupler according to claim 9, wherein the first bonding wire is connected directly to the light emitting element.

14. The optical coupler according to claim 9, wherein the first bonding wire is connected directly to the first part of the first lead frame.

15. The optical coupler according to claim 9, wherein at least one of the second, fourth, sixth, and eighth parts terminates as a cut end surface.

16. A method, comprising:
attaching a first chip to a first portion of a first frame element, the first frame element having a U-shaped portion between the first portion and a second portion that extends away from the U-shaped portion;
connecting a first wire from the first chip or the first portion of the frame element to the second portion of the first frame element;
encasing the first chip attached to the first portion of the first frame element in a first resin such that the U-shaped portion and a first end of the second portion of the first frame element protrude from the first resin;
separating the first and second portions of the first frame element by removal of a portion of the U-shaped portion of the first frame element while leaving a second end of the second portion and an end of the first portion protruding from the first resin; and
covering the first resin with a second resin such that the first end of the second portion protrudes out of the second resin and the second end of the second portion and the end of the first portion terminate in the second resin.

17. The method of 16, further comprising:
attaching a second chip to a first portion of a second frame element, the second frame element having a U-shaped portion between the first portion and a second portion extending away from the U-shaped portion;
connecting a second wire from the second chip or the first portion of the second frame element to the second portion of the second frame element;
placing the first and second frame elements in a facing arrangement such that the first and second chips are opposite one another;
encasing the second chip attached to the second frame element in the first resin while performing the encasing of the first chip attached to the first frame in the first resin, a first end of the second portion of the second frame element and the U-shaped portion of the second frame element protruding from the first resin;
separating the first and second portions of the second frame element by removal of a portion of the U-shaped portion of the second frame element while leaving a second end of the second portion of the second frame element and an end of the first portion of the second frame protruding from the first resin, wherein
the second end of the second portion and the end of the first portion of the second frame element terminate in the second resin after the first resin is covered by second resin.

18. The method of claim 17, wherein the second end of the second portion and the end of the first portion of the first frame element and the second end of the second portion and the end of the first portion of the second frame element protrude from the first resin in opposite directions.

19. The method of claim 17, wherein the second end of the second portion and the end of the first portion of the first frame element and the second end of the second portion and the end of the first portion of the second frame element protrude from the first resin in the same direction.

20. The method of claim 16, further comprising:
covering the first chip and a portion of the first wire in a third resin before encasing the first chip in the first resin.
